(19) United States
(12) Patent Application Publication
(10) Pub. No.: US 2016/0343525 A1
(43) Pub. Date: Nov. 24, 2016

(54) ELECTRONIC APPARATUS

(71) Applicant: Panasonic Intellectual Property Management Co., Ltd., Osaka (JP)

(72) Inventors: TAKASHI UMEDA, Osaka (JP); TAKESHI UEMURA, Osaka (JP); HIDEAKI FUJIURA, Osaka (JP)

(21) Appl. No.: 15/114,390

(22) PCT Filed: Feb. 2, 2015
(86) PCT No.: PCT/JP2015/000438

§ 371 Date: Jul. 26, 2016

(30) Foreign Application Priority Data
Mar. 17, 2014 (JP) 2014-053064

(51) Int. Cl. H01H 47/00; G01R 33/06; G01C 19/5776; G01P 15/08; H03K 17/00; H03F 3/45

(52) U.S. Cl. CPC H01H 47/00; H03K 17/005; H03F 3/45475; G01C 19/5776; G01P 15/08; G01R 33/06; H03F 2200/261; H03F 2203/45514; H03F 2203/45528

(57) ABSTRACT

A electronic apparatus includes a switching circuit including first and second circuits and a controller that controls the switching circuit. The first and second circuits process signals of first and second sensor elements, respectively. The controller switches between the first and second circuits of the switching circuit. The electronic apparatus can have a small size.

### TECHNICAL FIELD

The present invention relates to an electronic apparatus in which a controller can switch between at least two circuits in a switching circuit.

### BACKGROUND ART

PTLs 1 to 3 disclose conventional electronic apparatuses including processing circuits corresponding to sensors.

### CITATION LIST

### Patent Literatures

PTL 1: International Publication No. WO2013/153802

PTL 2: Japanese Patent Laid-Open Publication No. 2012-42261

PTL 3: Japanese Patent Laid-Open Publication No. 2011-169672

### SUMMARY

An electronic apparatus includes a switching circuit including first second circuits and a controller that controls the switching circuit. The first and second circuits are circuits that process signals of first and second sensor elements, respectively. The controller performs switching between the first and second circuits of the switching circuit.

The electronic apparatus can have a reduced size.

### BRIEF DESCRIPTION OF DRAWINGS

FIG. 1 is a schematic circuit diagram of an electronic apparatus according to an exemplary embodiment.

FIG. 2 is a schematic diagram of a switching circuit of the electronic apparatus according to the embodiment.

FIG. 3A is a schematic diagram of a first exemplary circuit configuration of the switching circuit of the electronic apparatus according to the embodiment.

FIG. 3B is a schematic diagram of the first exemplary circuit configuration of the switching circuit of the electronic apparatus according to the embodiment.

FIG. 3C is a schematic diagram of the first exemplary circuit configuration of the switching circuit of the electronic apparatus according to the embodiment.

FIG. 3D is a schematic diagram of another switching circuit of the electronic apparatus according to the embodiment.

FIG. 4A is a schematic diagram of a second exemplary circuit configuration of the switching circuit of the electronic apparatus according to the embodiment.

FIG. 4B is a schematic diagram of the second exemplary circuit configuration of the switching circuit of the electronic apparatus according to the embodiment.

FIG. 5A is a schematic diagram of a third exemplary circuit configuration of the switching circuit of the electronic apparatus according to the embodiment.

FIG. 5B is a schematic diagram of the third exemplary circuit configuration of the switching circuit of the electronic apparatus according to the embodiment.

FIG. 6A is a schematic diagram of a fourth exemplary circuit configuration of the switching circuit of the electronic apparatus according to the embodiment.

FIG. 6B is a schematic diagram of the fourth exemplary circuit configuration of the switching circuit of the electronic apparatus according to the embodiment.

### DETAIL DESCRIPTION OF PREFERRED EMBODIMENTS

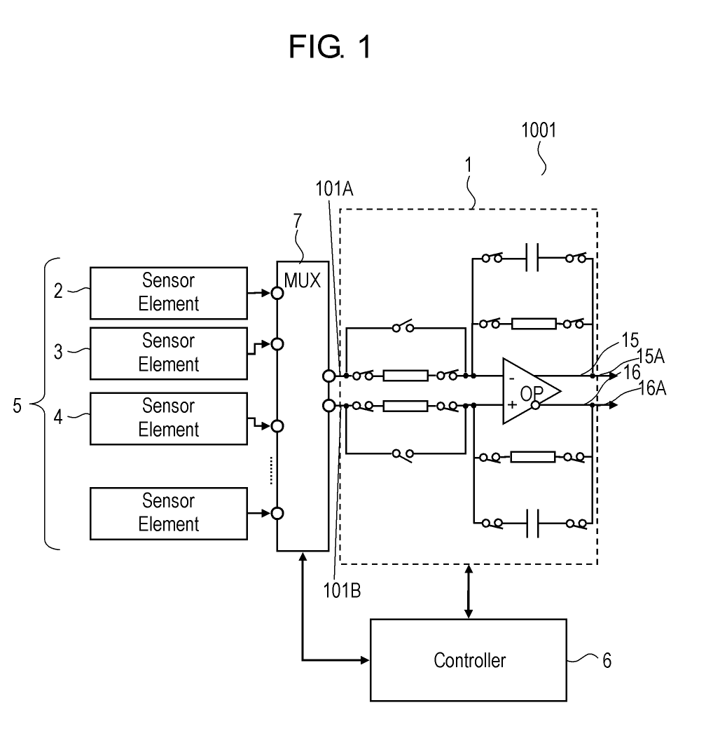

An electronic apparatus according to an exemplary embodiment will be described with reference to FIGS. 1 to 6B. In FIGS. 1 to 6B, the same components may not be denoted, and description thereof may not be repeated. FIGS. 1 to 6B and description illustrate preferred embodiments, and the present invention is not limited the illustrated configurations and shapes. Techniques described in the embodiment may be suitably combined within a reasonable range. In the following description, ordinal numbers, such as “first,” “second,” and “third”, are used in a first circuit, a second circuit, and a third circuit for convenience of description.

### (Basic Configuration)

FIG. 1 is a schematic diagram of electronic apparatus 1001 according to an exemplary embodiment. Electronic apparatus 1001 includes switching circuit 1 and controller 6 that controls switching circuit 1. Switching circuit 1 includes a first circuit and a second circuit. The first circuit is configured to process a signal of sensor element 2 while the second circuit is configured to process a signal of sensor element 3. Controller 6 can switch between the first circuit and the second circuit of switching circuit 1. With this configuration, the circuit for processing a signal of sensor element 2 or the circuit for processing a signal of sensor element 3 can be selected by switching in single switching circuit 1, hence reducing the size of entire electronic apparatus 1001. The first circuit and the second circuit preferably have a common portion. The common portion reduces the size of entire electronic apparatus 1001. The first circuit may be an amplifier circuit that amplifies a signal of sensor element 2, and the second circuit may be an amplifier circuit that amplifies a signal of sensor element 3.

As illustrated in FIG. 1, switching circuit 1 may further include a third circuit configured to process a signal of sensor element 4. The controller 6 switches among the first circuit, the second circuit, and the third circuit of switching circuit 1. With this configuration, the circuit for processing a signal of sensor element 2, the circuit for processing a signal of sensor element 3, and the circuit for processing a signal of sensor element 4 can be selected by switching in single switching circuit 1, hence reducing the size of entire electronic apparatus 1001. The third circuit may be an amplifier circuit that amplifies a signal of sensor element 4.

Switching circuit 1 is preferably connected to sensor element 2 and sensor element 3 via multiplexer 7. Multiplexer 7 and switching circuit 1 are preferably connectable in series to each other.

Controller 6 receives signals obtained from sensor elements 5 including sensor element 2 and sensor element 3. Based on the signals, controller 6 transmits, to switching circuit 1, a signal for selecting one circuit of the first circuit and the second circuit for signal processing of the sensor element. For example, in the case that a signal of sensor element 2 in switching circuit 1 is to be processed, a signal corresponding to sensor element 2 is input to controller 6, and controller 6 sends, to switching circuit 1, a selection signal indicating that the signal of sensor element 2 is processed by the first circuit. On the other hand, in the case that a signal of sensor element 3 in switching circuit 1 is to be processed, a signal corresponding to sensor element 3 is received by controller 6, and controller 6 sends, to switching circuit 1, a selection signal indicating that the signal of sensor element 3 is processed by the second circuit. Here, the signals sent from sensor elements 5 to controller 6 are preferably sent to controller 6 via multiplexer 7.

### (First Exemplary Circuit Configuration)

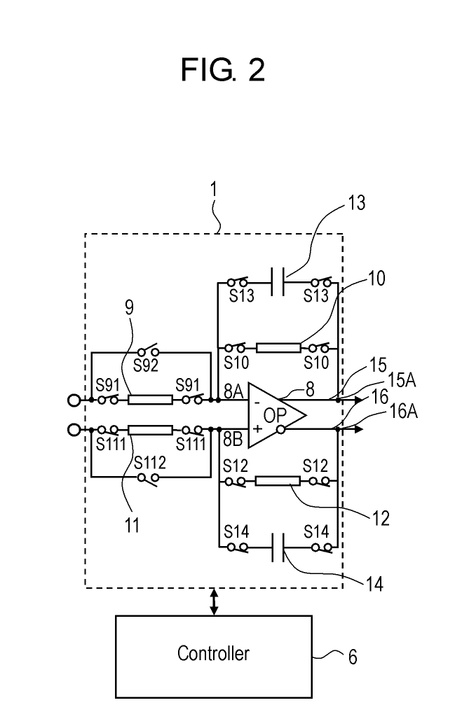

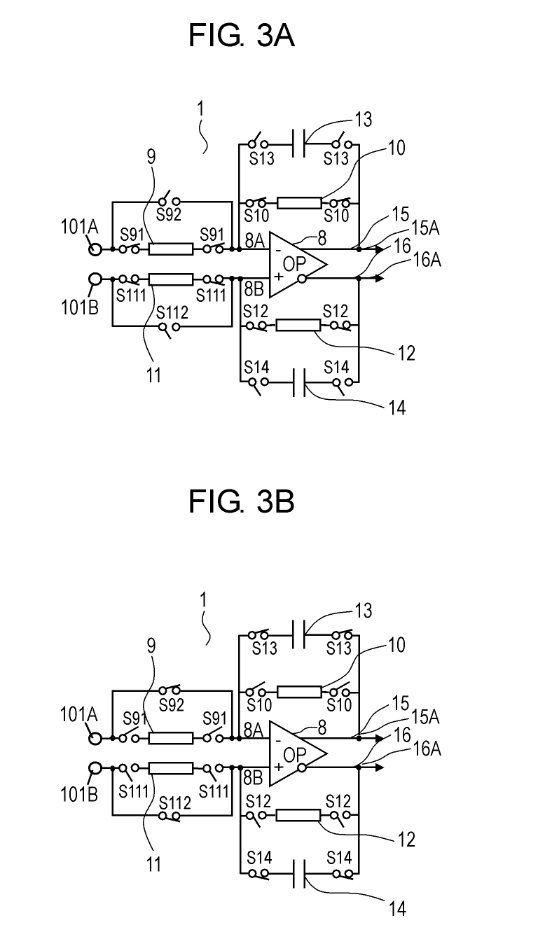

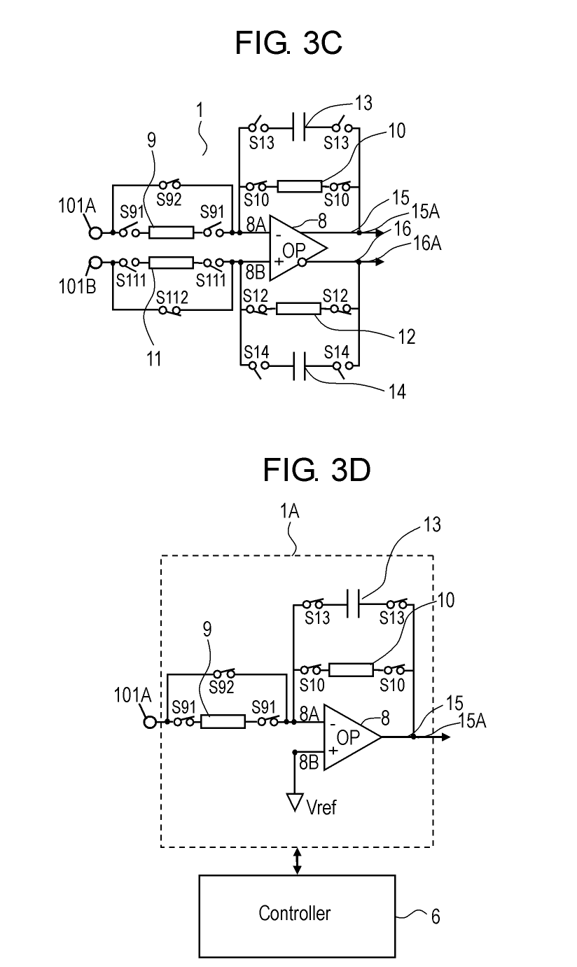

FIG. 2 is a schematic diagram of switching circuit 1. FIGS. 3A and 3B are schematic diagrams of a first exemplary circuit configuration of switching circuit 1. Switching circuit 1 preferably includes at least operational amplifier 8 having inverted input terminal 8A, non-inverted input terminal 8B, and output terminal 15, resistor 9 connectable in series to inverted input terminal 8A, resistor 10 connectable to inverted input terminal 8A and output terminal 15, and capacitor 13 connectable to inverted input terminal 8A and output terminal 15. The first exemplary circuit configuration of switching circuit 1 can be obtained by turning on and off the switches connected to the resistor and the capacitor, as illustrated in, e.g. FIGS. 3A and 3B.

Switching circuit 1 includes input port 101A and output port 15A. Output port 15A is connected to output terminal 15 of operational amplifier 8. Resistor 9 is connectable in series to input port 101A and inverted input terminal 8A between input port 101A and inverted input terminal 8A of operational amplifier 8. Resistor 10 is connectable in series to inverted input terminal 8A and output terminal 15 of operational amplifier 8 between inverted input terminal 8A and output terminal 15. Capacitor 13 is connectable in series to inverted input terminal 8A and output terminal 15 of operational amplifier 8 between inverted input terminal 8A and output terminal 15. Switching circuit 1 may further include switches S10, S13, S91, and S92. Switch S91 is connected in series to resistor 9 between input port 101A and inverted input terminal 8A. That is, switch S91 is connected in series to resistor 9 between inverted input terminal 8A and at least one sensor element of sensor elements 5. Switch S92 is connected in series to input port 101A and inverted input terminal 8A between input port 101A and inverted input terminal 8A. That is, switch S92 is connected in series to inverted input terminal 8A and at least one sensor element 5 of sensor elements 5 between inverted input terminal 8A and the one sensor element 5. Switch S10 is connected in series to resistor 10 between inverted input terminal 8A and output terminal 15. Switch S13 is connected in series to capacitor 13 between inverted input terminal 8A and output terminal 15. Controller 6 illustrated in FIG. 1 controls turning on and off of the switches.

Switching circuit 1 may further include input port 101B and output port 16A. Output port 16A is connected to output terminal 16 of operational amplifier 8. Switching circuit 1 may further include resistor 11 connectable in series to non-inverted input terminal 8B, resistor 12 connectable to non-inverted input terminal 8B and output terminal 16, and capacitor 14 connectable to non-inverted input terminal 8B and output terminal 16. That is, resistor 11 is connectable in series to input port 101B and non-inverted input terminal 8B between input port 101B and non-inverted input terminal 8B of operational amplifier 8. Resistor 12 is connectable in series to non-inverted input terminal 8B and output terminal 16 of operational amplifier 8 between non-inverted input terminal 8B and output terminal 16. Capacitor 14 is connectable in series to non-inverted input terminal 8B and output terminal 16 of operational amplifier 8 between non-inverted input terminal 8B and output terminal 16. In this case, switching circuit 1 further includes switches S12, S14, S111, and S112. Switch S111 is connected in series to resistor 11 between input port 101B and non-inverted input terminal 8B. That is, switch S111 is connected in series to resistor 11 between non-inverted input terminal 8B and at least one sensor element 5 of sensor elements 5. Switch S112 is connected in series to input port 101B and non-inverted input terminal 8B between input port 101B and non-inverted input terminal 8B. That is, switch S112 is connected in series to non-inverted input terminal 8B and at least one sensor element 5 of sensor elements 5 between the one sensor element 5 and non-inverted input terminal 8B. Switch S12 is connected in series to resistor 12 between non-inverted input terminal 8B and output terminal 16. Switch S14 is connected in series to capacitor 14 between non-inverted input terminal 8B and output terminal 16.

In switching circuit 1, resistor 9 is connectable in series between inverted input terminal 8A and at least one of sensor elements 2 and 3. Switch S91 is connected in series to inverted input terminal 8A and resistor 9. Resistor 10 is connectable to inverted input terminal 8A and output terminal 15. Switch S10 is connected in series to inverted input terminal 8A, output terminal 15, and resistor 10 between inverted input terminal 8A and output terminal 15. Capacitor 13 is connectable to inverted input terminal 8A and output terminal 15. Switch S13 is connected in series to inverted input terminal 8A, output terminal 15, and capacitor 13 between inverted input terminal 8A and output terminal 15. Switch S92 is connected between inverted input terminal 8A and at least one of sensor elements 2 and 3.

Sensor element 2 is configured to output a signal depending on a change in a resistance value of sensor element 2. Sensor element 3 is configured to output a signal depending on a change in a capacitance of sensor element 3. Sensor element 4 is configured to output a signal depending on a change in a current value of sensor element 4. Sensor element 2 may be preferably a magneto resistive (MR) device, a giant magneto resistive (GMR) device, or a Hall device. Sensor element 3 may be preferably a capacitance device including two electrodes forming a capacitance and storing charge between the electrodes. Sensor element 4 may preferably have a structure including a lower electrode, an upper electrode, and one of a pyroelectric film and a piezoelectric film made of piezoelectric material, such as PZT, sandwiched between the lower electrode and the upper electrode. As application, for example, sensor element 2 is preferably a magnetism sensor, sensor element 3 is preferably an angular velocity sensor or an acceleration sensor, and sensor element 4 is preferably an angular velocity sensor or a gesture sensor.

FIG. 3A illustrates switching circuit 1 forming the first circuit. In the case that a signal from sensor element 2 is processed, as illustrated in FIG. 3A, the first circuit is obtained such that resistor 9 is connected in series to inverted input terminal 8A, resistor 10 is connected to inverted input terminal 8A and output terminal 15, and capacitor 13 is not connected to any of inverted input terminal 8A and output terminal 15. In this case, capacitor 13 is not connected to at least one of inverted input terminal 8A and output terminal 15.

Specifically, in order to have switching circuit 1 function as the first circuit, in a case where a signal of sensor element 2 out of sensor elements 5 is supplied via multiplexer 7 illustrated in FIG. 1 to input ports 101A and 101B of switching circuit 1, controller 6 turns on switches S10, S12, S91, and S111 and turns off switches S13, S14, S92, and S112. This control connects resistor 9 in series to input port 101A and inverted input terminal 8A between input port 101A and inverted input terminal 8A, and connects resistor 11 in series to input port 101B and non-inverted input terminal 8B between input port 101B and non-inverted input terminal 8B. In addition, resistor 10 is connected in series to inverted input terminal 8A and output terminal 15 between inverted input terminal 8A and output terminal 15, and resistor 12 is connected in series to non-inverted input terminal 8B and output terminal 16 between non-inverted input terminal 8B and output terminal 16. In addition, capacitor 13 is not connected to any of inverted input terminal 8A and output terminal 15, or alternatively, is not connected to at least one of inverted input terminal 8A and output terminal 15. Capacitor 14 is not connected to any of non-inverted input terminal 8B and output terminal 16, or alternatively, is not connected to at least one of non-inverted input terminal 8B and output terminal 16. Controller 6 thus causes switching circuit 1 to function as the first circuit that processes a signal of sensor element 2 to obtain the first circuit. A difference between output signals from output terminals 15 and 16 is obtained so that an accurate output signal can be obtained. In this case, signals of sensor element 2 to be supplied to input ports 101A and 101B of switching circuit 1 may be balanced signals.

FIG. 3B illustrates switching circuit 1 forming the second circuit. In the case that a signal from sensor element 3 is processed, as illustrated in FIG. 3B, the second circuit is obtained such that capacitor 13 is connected to inverted input terminal 8A and output terminal 15, resistor 9 is not connected in series to inverted input terminal 8A, and resistor 10 is not connected to any of inverted input terminal 8A and output terminal 15. In this case, resistor 10 is not connected to at least one of inverted input terminal 8A and output terminal 15.

Specifically, in order to have switching circuit 1 function as the second circuit, in a case where a signal of sensor element 3 out of sensor elements 5 is supplied via multiplexer 7 illustrated in FIG. 1 to input ports 101A and 101B of switching circuit 1, controller 6 turns on switches S13, S14, S92, and S112 and turns off switches S10, S12, S91, and S111. This control connects input port 101A to inverted input terminal 8A, and connects input port 101B to non-inverted input terminal 8B. Capacitor 13 is connected in series to inverted input terminal 8A and output terminal 15 between inverted input terminal 8A and output terminal 15, and capacitor 14 is connected in series to non-inverted input terminal 8B and output terminal 16 between non-inverted input terminal 8B and output terminal 16. Resistor 10 is not connected to any of inverted input terminal 8A and output terminal 15, or alternatively, is not connected to at least one of inverted input terminal 8A and output terminal 15. Resistor 12 is not connected to any of non-inverted input terminal 8B and output terminal 16, or alternatively, is not connected to at least one of non-inverted input terminal 8B and output terminal 16. Controller 6 thus causes switching circuit 1 to function as the second circuit that processes a signal of sensor element 3 to obtain the second circuit. A difference between output signals from output terminals 15 and 16 is obtained so that an accurate output signal can be obtained. In this case, signals of sensor element 3 to be supplied to input ports 101A and 101B of switching circuit 1 may be balanced signals. In the second circuit illustrated in FIG. 3B, resistors 9 and 11 are short-circuited with switches S92 and S112, respectively. Thus, controller 6 may turn on at least one of switches S91 and S111 to connect resistor 9 to at least one of input port 101A and inverted input terminal 8A, or alternatively, to connect resistor 11 to at least one of input port 101B and non-inverted input terminal 8B.

FIG. 3C illustrates switching circuit 1 forming the third circuit. In the case a signal from sensor element 4 is processed, as illustrated in FIG. 3C, the third circuit is obtained such that resistor 9 is not connected in series to inverted input terminal 8A, resistor 10 is connected to inverted input terminal 8A and output terminal 15, and capacitor 13 is not connected to any of inverted input terminal 8A and output terminal 15. In this case, the capacitor 13 is not connected to at least one of inverted input terminal 8A or output terminal 15.

Specifically, in order to have switching circuit 1 function as the third circuit, in a case where a signal of sensor element 4 out of sensor elements 5 is supplied via multiplexer 7 illustrated in FIG. 1 to input ports 101A and 101B of switching circuit 1, controller 6 turns on switches S10, S12, S92, and S112 and turns off switches S13, S14, S91, and S111. This control connects input port 101A to inverted input terminal 8A, and connects input port 101B to non-inverted input terminal 8B. In addition, resistor 10 is connected in series to inverted input terminal 8A and output terminal 15 between inverted input terminal 8A and output terminal 15, and resistor 12 is connected in series to non-inverted input terminal 8B and output terminal 16 between non-inverted input terminal 8B and output terminal 16. Capacitor 13 is not connected to any of inverted input terminal 8A and output terminal 15, or alternatively, is not connected to at least one of inverted input terminal 8A and output terminal 15. Capacitor 14 is not connected to any of non-inverted input terminal 8B and output terminal 16, or alternatively, is not connected to at least one of non-inverted input terminal 8B and output terminal 16. Controller 6 thus causes switching circuit 1 to function as the third circuit that processes a signal of sensor element 4 to obtain the third circuit. A difference between output signals from output terminals 15 and 16 is obtained so that an accurate output signal can be obtained. In this case, signals of sensor element 4 to be supplied to input ports 101A and 101B of switching circuit 1 may be balanced signals. In the third circuit illustrated in FIG. 3C, resistors 9 and 11 are short-circuited with switches S92 and S112, respectively. Thus, controller 6 may turn on at least one of switches S91 and S111 so that resistor 9 is connected to at least one of input port 101A and inverted input terminal 8A, or alternatively, resistor 11 is connected to at least one of input port 101B and non-inverted input terminal 8B.

The conventional electronic apparatuses disclosed in PTLs 1 to 3 require processing circuits individually corresponding to sensors, hence having a large size.

In the electronic apparatus 1001 according to the embodiment, at least two circuits (the first circuit and the second circuit) of the switching circuit 1 can be switched by controller 6, hence reducing the size of entire electronic apparatus 1001.

In switching circuit 1 illustrated in FIGS. 3A and 3B, two switches S10 turn on and off simultaneously, two switches S12 are turned on and off simultaneously, two switches S13 are turned on and off simultaneously, two switches S14 are turned on and off simultaneously, two switches S91 are turned on and off simultaneously, and two switches S111 are turned on and off simultaneously. Switching circuit 1 according to the embodiment may be configured such that at least one of two switches S10 is turned on and off, at least one of two switches S12 is turned on and off, at least one of two switches S13 is turned on and off, at least one of two switches S14 is turned on and off, at least one of two switches S91 is turned on and off, and at least one of two switches S111 is turned on and off.

As illustrated in FIG. 2, switching circuit 1 may further include resistor 11 connectable in series to the non-inverted input terminal, resistor 12 connectable to the non-inverted input terminal and output terminal 16, and capacitor 14 connectable to the non-inverted input terminal and output terminal 16. A difference between output signals from output terminals 15 and 16 is obtained so that an accurate output signal can be obtained. Connection configurations for obtaining the first circuit, the second circuit, and the third circuit are the same at the side of inverted input terminal 8A and the side of non-inverted input terminal 8B, and thus, description thereof will not be repeated.

FIG. 3D is a schematic diagram of another switching circuit 1A of electronic apparatus 1001 according to the embodiment. In FIG. 3D, components identical to those of switching circuit 1 illustrated in FIG. 2 are denoted by the same reference numerals. Switching circuit 1A illustrated in FIG. 3D includes none of resistors 11 and 12 and capacitor 14 described above. Operational amplifier 8 does not have output terminal 16. Non-inverted input terminal 8B of operational amplifier 8 is connected to reference voltage Vref having a predetermined voltage, such as a ground.

### (Second Exemplary Circuit Configuration)

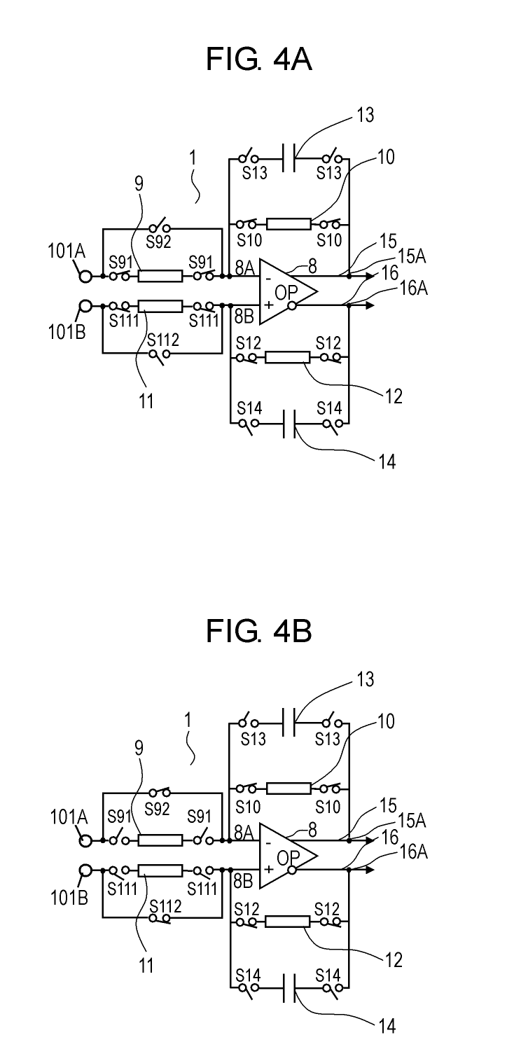

FIGS. 4A and 4B illustrate a second exemplary circuit configuration of switching circuit 1 of the electronic apparatus according to the embodiment. The second exemplary circuit configuration in switching circuit 1 can be obtained by turning on and off the switches connected to resistors and capacitors, as illustrated in, e.g. FIGS. 4A and 4B.

As illustrated in FIGS. 2, 4A, and 4B, switching circuit 1 preferably includes at least operational amplifier 8 having inverted input terminal 8A, non-inverted input terminal 8B, and output terminal 15, resistor 9 connectable in series to inverted input terminal 8A, and resistor 10 connectable to inverted input terminal 8A and output terminal 15.

Sensor element 2 is configured to output a signal depending on a change in a resistance value thereof while sensor element 3 is configured to output a signal depending on a change in a current value of sensor element 3. Sensor element 2 may be preferably an MR device, a GMR device, or a Hall device. Sensor element 3 may preferably have a structure including a lower electrode, an upper electrode, and one of a pyroelectric film and a piezoelectric film made of material, such as PZT sandwiched between the lower electrode and the upper electrode.

FIG. 4A illustrates switching circuit 1 forming the first circuit. In the case a signal from sensor element 2 is processed, as illustrated in FIG. 4A, the first circuit is obtained such that resistor 9 is connected in series to inverted input terminal 8A, and resistor 10 is connected to inverted input terminal 8A and output terminal 15.

Specifically, in order to have switching circuit 1 function as the first circuit, in a case where a signal of sensor element 2 out of sensor elements 5 is supplied via multiplexer 7 illustrated in FIG. 1 to input ports 101A and 101B of switching circuit 1, controller 6 turns on switches S10, S12, S91, and S111 and turns off switches S13, S14, S92, and S112. This control connects resistor 9 in series to input port 101A and inverted input terminal 8A between input port 101A and inverted input terminal 8A, and connects resistor 11 in series to input port 101B and non-inverted input terminal 8B between input port 101B and non-inverted input terminal 8B. In addition, resistor 10 is connected in series to inverted input terminal 8A and output terminal 15 between inverted input terminal 8A and output terminal 15, and resistor 12 is connected in series to non-inverted input terminal 8B and output terminal 16 between non-inverted input terminal 8B and output terminal 16. Capacitor 13 is not connected to any of inverted input terminal 8A and output terminal 15, or alternatively, is not connected to at least one of inverted input terminal 8A and output terminal 15. Capacitor 14 is not connected to any of non-inverted input terminal 8B and output terminal 16, or alternatively, is not connected to at least one of non-inverted input terminal 8B and output terminal 16. Controller 6 thus causes switching circuit 1 to function as the first circuit that processes a signal of sensor element 2 to obtain the first circuit. A difference between output signals from output terminals 15 and 16 is obtained so that an accurate output signal can be obtained. In this case, signals of sensor element 2 to be supplied to input ports 101A and 101B of switching circuit 1 may be balanced signals.

FIG. 4B illustrates switching circuit 1 forming the second circuit. In the case a signal from sensor element 3 is processed, as illustrated in FIG. 4B, the second circuit is obtained such that resistor 9 is not connected in series to inverted input terminal 8A, and resistor 10 is connected to inverted input terminal 8A and output terminal 15.

Specifically, in order to have switching circuit 1 function as the second circuit, in a case where a signal of sensor element 4 out of sensor elements 5 is supplied via multiplexer 7 illustrated in FIG. 1 to input ports 101A and 101B of switching circuit 1, controller 6 turns on switches S10, S12, S92, and S112 and turns off switches S13, S14, S91, and S111. This control connects input port 101A to inverted input terminal 8A, and connects input port 101B to non-inverted input terminal 8B. In addition, resistor 10 is connected in series to inverted input terminal 8A and output terminal 15 between inverted input terminal 8A and output terminal 15, and resistor 12 is connected in series to non-inverted input terminal 8B and output terminal 16 between non-inverted input terminal 8B and output terminal 16. Capacitor 13 is not connected to any of inverted input terminal 8A and output terminal 15, or alternatively, is not connected to at least one of inverted input terminal 8A and output terminal 15. Capacitor 14 is not connected to any of non-inverted input terminal 8B and output terminal 16, or alternatively, is not connected to at least one of non-inverted input terminal 8B and output terminal 16. Controller 6 thus causes switching circuit 1 to function as the second circuit that processes a signal of sensor element 4 to obtain the second circuit. A difference between output signals from output terminals 15 and 16 is obtained so that an accurate output signal can be obtained. In this case, signals of sensor element 4 to be supplied to input ports 101A and 101B of switching circuit 1 may be balanced signals. In the second circuit illustrated in FIG. 4B, resistors 9 and 11 are short-circuited by switches S92 and S112, respectively. Thus, controller 6 may turn on at least one of switches S91 and S111 to connect resistor 9 to at least one of input port 101A and inverted input terminal 8A, or alternatively, resistor 11 is connected to at least one of input port 101B and non-inverted input terminal 8B.

As illustrated in FIG. 2, switching circuit 1 preferably further includes resistor 11 connectable in series to non-inverted input terminal 8B, and resistor 12 connectable to non-inverted input terminal 8B and output terminal 16. Connection configurations for obtaining the first circuit and the second circuit are the same at the side of inverted input terminal 8A and the side of non-inverted input terminal 8B, and thus, description thereof will not be repeated. As in switching circuit 1A illustrated in FIG. 3D, the configuration may not be provided. In this case, non-inverted input terminal 8B is connected to reference voltage Vref having a predetermined voltage, such as a ground.

In the second exemplary circuit configuration illustrated in FIGS. 4A and 4B, switching circuit 1 may not include capacitors 13 and 14 and switches S13 and S14. In a case where switching circuit 1 includes capacitors 13 and 14, capacitor 13 is not connected to any of inverted input terminal 8A and output terminal 15, or alternatively, is not connected to at least one of inverted input terminal 8A and output terminal 15. Capacitor 14 is not connected to any of non-inverted input terminal 8B and output terminal 16, or alternatively, is not connected to at least one of non-inverted input terminal 8B and output terminal 16.

### (Third Exemplary Circuit Configuration)

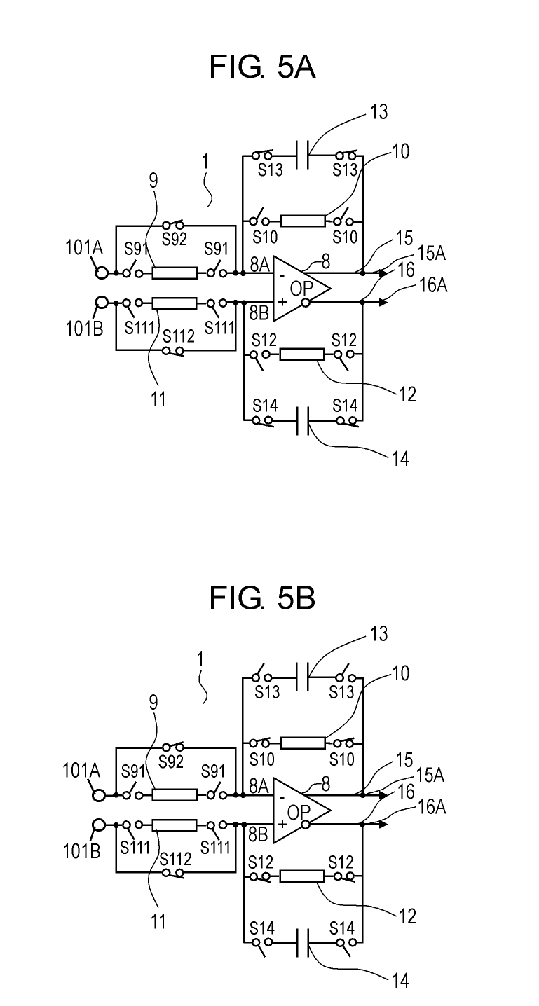

FIGS. 5A and 5B illustrate a third exemplary circuit configuration of switching circuit 1 of the electronic apparatus according to the embodiment. The third exemplary circuit configuration in switching circuit 1 can be obtained by turning on and off the switches connected to a resistor and a capacitor, as illustrated in, e.g. FIGS. 5A and 5B.

As illustrated in FIGS. 2, 5A, and 5B, switching circuit 1 preferably includes at least operational amplifier 8 having inverted input terminal 8A, non-inverted input terminal 8B, and output terminal 15, resistor 10 connectable to inverted input terminal 8A and output terminal 15, and capacitor 13 connectable to non-inverted input terminal 8A and output terminal 15.

Sensor element 2 is configured to output a signal depending on a change in a capacitance of sensor element 2, and sensor element 3 is configured to output a signal depending on a change in a current value of sensor element 3. Sensor element 2 may be preferably a capacitance device including two electrodes that form a capacitance and can store charge between the two electrodes. Sensor element 3 may preferably have a structure including a lower electrode, an upper electrode, and one of a pyroelectric film and a piezoelectric film made of piezoelectric material, such as PZT, sandwiched between the lower electrode and the upper electrode.

FIG. 5A illustrates switching circuit 1 forming the first circuit. In the case that a signal from sensor element 2 is processed, as illustrated in FIG. 5A, the first circuit is obtained such that capacitor 13 is connected to inverted input terminal 8A and output terminal 15, and resistor 10 is not connected to any of inverted input terminal 8A and output terminal 15. In this case, the resistor is not connected to at least one of inverted input terminal 8A and output terminal 15.

Specifically, in order to have switching circuit 1 function as the first circuit, in a case where a signal of sensor element 3 out of sensor elements 5 is supplied via multiplexer 7 illustrated in FIG. 1 to input ports 101A and 101B of switching circuit 1, controller 6 turns on switches S13, S14, S92, and S112 and turns off switches S10, S12, S91, and S111. This control connects input port 101A to inverted input terminal 8A, and connects input port 101B to non-inverted input terminal 8B. In addition, capacitor 13 is connected in series to inverted input terminal 8A and output terminal 15 between inverted input terminal 8A and output terminal 15, and capacitor 14 is connected in series to non-inverted input terminal 8B and output terminal 16 between non-inverted input terminal 8B and output terminal 16. Resistor 10 is not connected to any of inverted input terminal 8A and output terminal 15, or alternatively, is not connected to at least one of inverted input terminal 8A or output terminal 15. Resistor 12 is not connected to any of non-inverted input terminal 8B and output terminal 16, or alternatively, is not connected to at least one of non-inverted input terminal 8B or output terminal 16. Controller thus 6 causes switching circuit 1 to function as the first circuit that processes a signal of sensor element 3 to obtain the first circuit. A difference between output signals from output terminals 15 and 16 is obtained so that an accurate output signal can be obtained. In this case, a signal of sensor element 3 to be supplied to input ports 101A and 101B of switching circuit 1 may be a balanced signal. In the first circuit illustrated in FIG. 5A, resistors 9 and 11 are short-circuited by using switches S92 and S112, respectively. Thus, controller 6 may turn on at least one of switches S91 and S111 so that resistor 9 is connected to at least one of input port 101A and inverted input terminal 8A, or alternatively, resistor 11 is connected to at least one of input port 101B and non-inverted input terminal 8B.

FIG. 5B illustrates switching circuit 1 when obtaining the second circuit. In the case of processing a signal from sensor element 3, as illustrated in FIG. 5B, the second circuit is obtained in such that resistor 10 is connected to inverted input terminal 8A and output terminal 15, and capacitor 13 is not connected to any of inverted input terminal 8A and output terminal 15. Capacitor 13 is not connected to at least one of inverted input terminal 8A or output terminal 15.

Specifically, in order to have switching circuit 1 function as the second circuit, in a case where a signal of sensor element 4 out of sensor elements 5 is supplied via multiplexer 7 illustrated in FIG. 1 to input ports 101A and 101B of switching circuit 1, controller 6 turns on switches S10, S12, S92, and S112 and turns off switches S13, S14, S91, and S111. This control connects input port 101A to inverted input terminal 8A, and connects input port 101B to non-inverted input terminal 8B. In addition, resistor 10 is connected in series to inverted input terminal 8A and output terminal 15 between inverted input terminal 8A and output terminal 15, and resistor 12 is connected in series to non-inverted input terminal 8B and output terminal 16 between non-inverted input terminal 8B and output terminal 16. Capacitor 13 is not connected to any of inverted input terminal 8A and output terminal 15, or alternatively, is not connected to at least one of inverted input terminal 8A or output terminal 15. Capacitor 14 is not connected to any of non-inverted input terminal 8B and output terminal 16, or alternatively, is not connected to at least one of non-inverted input terminal 8B or output terminal 16. Controller 6 thus causes switching circuit 1 to function as the second circuit that processes a signal of sensor element 4 to obtain the second circuit. A difference between output signals from output terminals 15 and 16 is obtained so that an accurate output signal can be obtained. In this case, signals of sensor element 4 to be supplied to input ports 101A and 101B of switching circuit 1 may be balanced signals. In the second circuit illustrated in FIG. 5B, resistors 9 and 11 are short-circuited by using switches S92 and S112, respectively. Thus, controller 6 may turn on at least one of switches S91 and S111 so that resistor 9 is connected to at least one of input port 101A and inverted input terminal 8A, or alternatively, resistor 11 is connected to at least one of input port 101B and non-inverted input terminal 8B.

As illustrated in FIG. 2, switching circuit 1 preferably further includes resistor 12 connectable to non-inverted input terminal 8B and output terminal 16, and capacitor 14 connectable to non-inverted input terminal 8B and output terminal 16. Connection configurations for obtaining the first circuit and the second circuit are the same at the side of inverted input terminal 8A and the side of non-inverted input terminal 8B, and thus, description thereof will not be repeated. As in switching circuit 1A illustrated in FIG. 3D does not include the configuration. In this case, non-inverted input terminal 8B is connected to reference voltage Vref having a predetermined voltage, such as ground.

Switching circuit 1 illustrated in FIGS. 5A and 5B may not include resistors 9 and 11 and switches S91 and S111. In a case where input port 101A and input port 101B are connected to inverted input terminal 8A and non-inverted input terminal 8B of operational amplifier 8, respectively, switching circuit 1 may not include switches S92 and S112. In a case where switching circuit 1 includes resistors 9 and 11, resistor 9 is not connected to any of inverted input terminal 8A and output terminal 15, or alternatively, is not connected to at least one of inverted input terminal 8A or output terminal 15, and resistor 11 is not connected to any of non-inverted input terminal 8B and output terminal 16, or alternatively, is not connected to at least one of non-inverted input terminal 8B and output terminal 16.

### (Fourth Exemplary Circuit Configuration)

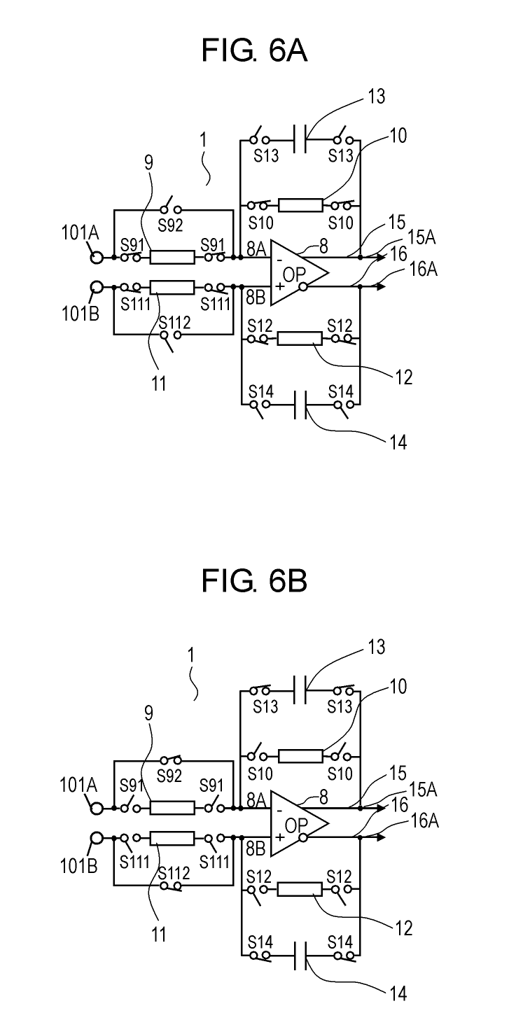

FIGS. 6A and 6B illustrate a fourth exemplary circuit configuration of switching circuit 1 of the electronic apparatus according to the embodiment. The fourth exemplary circuit configuration of switching circuit 1 can be obtained by turning on and off the switches connected to a resistor and a capacitor, as illustrated in, e.g. FIGS. 6A and 6B.

As illustrated in FIGS. 2, 6A, and 6B, switching circuit 1 preferably includes at least operational amplifier 8 having inverted input terminal 8A, non-inverted input terminal 8B, and output terminal 15, resistor 9 serially connectable to inverted input terminal 8A, resistor 10 connectable to inverted input terminal 8A and output terminal 15, and capacitor 13 connectable to inverted input terminal 8A and output terminal 15.

Sensor element 2 is a device that outputs a signal depending on a change in resistance value of sensor element 2, and sensor element 3 is a device that outputs a signal depending on a change in capacitance of sensor element 3. Sensor element 2 is preferably, for example, an MR device, a GMR device, or a Hall device. Sensor element 3 is preferably, for example, a capacitance device that two includes electrodes forming a capacitance and storing charge between the electrodes.

In the case of processing a signal from sensor element 2, as illustrated in FIG. 6A, the first circuit is obtained such that resistor 9 is connected in series to inverted input terminal 8A, resistor 10 is connected to inverted input terminal 8A and output terminal 15, and capacitor 13 is not connected to any of non-inverted input terminal 8A and output terminal 15. In this case, capacitor 13 is not connected to at least one of inverted input terminal 8A and output terminal 15.

Specifically, on order to have switching circuit 1 function as the first circuit, in a case where a signal of sensor element 2 out of sensor elements 5 is supplied via multiplexer 7 illustrated in FIG. 1 to input ports 101A and 101B of switching circuit 1, controller 6 turns on switches S10, S12, S91, and S111 and turns off switches S13, S14, S92, and S112. This control connects resistor 9 in series to input port 101A and inverted input terminal 8A between input port 101A and inverted input terminal 8A, and connects resistor 11 in series to input port 101B and non-inverted input terminal 8B between input port 101B and non-inverted input terminal 8B. In addition, resistor 10 is serially connected to inverted input terminal 8A and output terminal 15 between inverted input terminal 8A and output terminal 15, and resistor 12 is serially connected to non-inverted input terminal 8B and output terminal 16 between non-inverted input terminal 8B and output terminal 16. Capacitor 13 is not connected to any of inverted input terminal 8A and output terminal 15, or alternatively, is not connected to at least one of inverted input terminal 8A and output terminal 15. Capacitor 14 is not connected to any of non-inverted input terminal 8B and output terminal 16, or alternatively, is not connected to at least one of non-inverted input terminal 8B and output terminal 16. Controller 6 thus causes switching circuit 1 to function as the first circuit that processes a signal of sensor element 2 to obtain the first circuit. A difference between output signals from output terminals 15 and 16 is obtained so that an accurate output signal can be obtained. In this case, signals of sensor element 2 to be supplied to input ports 101A and 101B of switching circuit 1 may be balanced signals.

In the case of processing a signal from sensor element 3, as illustrated in FIG. 6B, the second circuit can be obtained such that capacitor 13 is connected to inverted input terminal 8A and output terminal 15, resistor 9 is not connected in series to inverted input terminal 8A, and resistor 10 is not connected to any of inverted input terminal 8A and output terminal 15. In this case, resistor 10 is not connected to at least one of inverted input terminal 8A and output terminal 15.

Specifically, in order to have switching circuit 1 function as the second circuit, in a case where a signal of sensor element 3 out of sensor elements 5 is supplied via multiplexer 7 illustrated in FIG. 1 to input ports 101A and 101B of switching circuit 1, controller 6 turns on switches S13, S14, S92, and S112 and turns off switches S10, S12, S91, and S111. This control connects input port 101A to inverted input terminal 8A, and connects input port 101B to non-inverted input terminal 8B. In addition, capacitor 13 is connected in series to inverted input terminal 8A and output terminal 15 between inverted input terminal 8A and output terminal 15, and capacitor 14 is connected in series to non-inverted input terminal 8B and output terminal 16 between non-inverted input terminal 8B and output terminal 16. Resistor 10 is not connected to any of inverted input terminal 8A and output terminal 15, or alternatively, is not connected to at least one of inverted input terminal 8A and output terminal 15. Resistor 12 is not connected to any of non-inverted input terminal 8B and output terminal 16, or alternatively, is not connected to at least one of non-inverted input terminal 8B and output terminal 16. Controller 6 thus causes switching circuit 1 to function as the second circuit that processes a signal of sensor element 3 to obtain the second circuit. A difference between output signals from output terminals 15 and 16 is obtained so that an accurate output signal can be obtained. In this case, signals of sensor element 3 to be supplied to input ports 101A and 101B of switching circuit 1 may be balanced signals. In the second circuit illustrated in FIG. 6B, resistors 9 and 11 are short-circuited by switches S92 and S112, respectively. Thus, controller 6 may turn on at least one of switches S91 and S111 so that resistor 9 is connected to at least one of input port 101A and inverted input terminal 8A, or alternatively, resistor 11 is connected to at least one of input port 101B and non-inverted input terminal 8B.

As illustrated in FIG. 2, switching circuit 1 may further include resistor 11 connectable in series to the non-inverted input terminal, resistor 12 connectable to the non-inverted input terminal and output terminal 16, and capacitor 14 connectable to the non-inverted input terminal and output terminal 16. Connection configurations for obtaining the first circuit and the second circuit are the same at the side of inverted input terminal 8A and the side of non-inverted input terminal 8B, and thus, description thereof will not be repeated. As in switching circuit 1A illustrated in FIG. 3D, the configuration may not be provided. In this case, non-inverted input terminal 8B is connected to reference voltage Vref having a predetermined voltage, such as a ground.

### INDUSTRIAL APPLICABILITY

In an electronic apparatus according to the present invention, a controller can switch between at least two circuits in a switching circuit, hence reducing the size of an entire system of various sensors, such as an angular velocity sensor, an acceleration sensor, a magnetism sensor, and a gesture sensor.

### REFERENCE MARKS IN THE DRAWINGS

1 switching circuit
2 sensor element (first sensor element)
3 sensor element (second sensor element)
4 sensor element (third sensor element)
6 controller
7 multiplexer
8 operational amplifier
8A inverted input terminal
8B non-inverted input terminal
9 resistor (first resistor)
10 resistor (second resistor)
11 resistor (third resistor)
12 resistor (fourth resistor)
13 capacitor (first capacitor)
14 capacitor (second capacitor)
15 output terminal (first output terminal)
16 output terminal (second output terminal)
S10 switch (second switch)
S13 switch (third switch)
S91 switch (first switch)
S92 switch (third switch, fourth switch)

1. An electronic apparatus comprising:
a switching circuit including a first circuit and a second circuit; and
a controller for controlling the switching circuit,
wherein the first circuit is configured to process a signal of a first sensor element,
wherein the second circuit is configured to process a signal of a second sensor element,
wherein the controller is configured to switch between the first circuit and the second circuit of the switching circuit, and
wherein the switching circuit includes:
an operational amplifier having an inverted input terminal, a non-inverted input terminal, and an output terminal;
a first resistor connectable in series to the inverted input terminal; and
a second resistor connectable to the inverted input terminal and the output terminal.

2. The electronic apparatus of claim 1,
wherein the first circuit is an amplifier circuit that amplifies a signal of the first sensor element, and
wherein the second circuit is an amplifier circuit that amplifies a signal of the second sensor element.

3. The electronic apparatus of claim 1,
wherein the switching circuit is connected to the first sensor element and the second sensor element via a multiplexer, and
wherein the multiplexer is connectable in series to the switching circuit.

4. (canceled)

5. The electronic apparatus of claim 1, wherein the switching circuit further includes a capacitor connectable to the inverted input terminal and the output terminal.

6. The electronic apparatus of claim 1, wherein the switching circuit further includes a first capacitor connectable to the inverted input terminal and the first output terminal.

7. The electronic apparatus of claim 6,
wherein the operational amplifier further has a second output terminal, and
wherein the switching circuit includes:
a third resistor connectable in series to the non-inverted input terminal;
a fourth resistor connectable to the non-inverted input terminal and the second output terminal; and
a second capacitor connectable to the non-inverted input terminal and the second output terminal.

8. The electronic apparatus of claim 6, wherein the controller is configured to allow the switching circuit to function as the first circuit by:
connecting the first resistor in series to the inverted input terminal;
connecting the second resistor to the inverted input terminal and the first output terminal; and
not connecting the first capacitor to at least one of the inverted input terminal and the first output terminal.

9. The electronic apparatus of claim 6, wherein the controller is configured to allow the switching circuit to function as the second circuit by:
not connecting the first resistor in series to the inverted input terminal;
not connecting the second resistor to at least one of the inverted input terminal and the first output terminal; and
connecting the first capacitor to the inverted input terminal and the first output terminal.

10. The electronic apparatus of claim 1, wherein the first sensor element outputs a signal based on a change in a resistance value of the first sensor element.

11. The electronic apparatus of claim 1, wherein the second sensor element outputs a signal based on a change in a capacitance of the second sensor element.

12. The electronic apparatus of claim 1,
wherein the switching circuit further includes a third circuit,
wherein the third circuit is configured to process a signal of a third sensor element, and
wherein the controller is configured to switch among the first circuit, the second circuit, and the third circuit of the switching circuit.

13. The electronic apparatus of claim 12, wherein the third circuit is an amplifier circuit that amplifies a signal of the third sensor element.

14. The electronic apparatus of claim 12,
wherein the switching circuit further includes a capacitor connectable to the inverted input terminal and the output terminal,
wherein the controller is configured to allow the switching circuit to function as the third circuit by:
not connecting the first resistor in series to the inverted input terminal,
connecting the second resistor to the inverted input terminal and the output terminal, and
not connecting the capacitor to at least one of the inverted input terminal and the output terminal.

15. The electronic apparatus of claim 12, wherein the third sensor element outputs a signal based on a change in a current value flowing in the third sensor element.

16. (canceled)

17. (canceled)

18. (canceled)

19. (canceled)

20. (canceled)

21. (canceled)

22. (canceled)

23. (canceled)

24. (canceled)

25. An electronic apparatus comprising:
a switching circuit configured to process a signal of a first sensor element and a signal of a second sensor element; and
a controller configured to control the switching circuit,
wherein the switching circuit includes:
an operational amplifier having an inverted input terminal, a non-inverted input terminal, and an output terminal;
a first resistor connectable in series between the inverted input terminal and at least one of the first sensor element and the second sensor element;
a first switch connected in series to the inverted input terminal and the first resistor,
a second resistor serially connectable to the inverted input terminal and the output terminal, and
a second switch connected in series to the inverted input terminal, the output terminal, and the second resistor between the inverted input terminal and the output terminal.

26. The electronic apparatus of claim 25, wherein the switching circuit includes:
a capacitor connectable to the inverted input terminal and the output terminal, and
a third switch connected in series to the inverted input terminal, the output terminal, and the capacitor between the inverted input terminal and the output terminal.

27. The electronic apparatus of claim 26, wherein the switching circuit further includes a fourth switch connectable in series between the inverted input terminal and the at least one of the first sensor element and the second sensor element.

28. The electronic apparatus of claim 25, wherein the switching circuit further includes a third switch connectable in series between the inverted input terminal and the at least one of the first sensor element or the second sensor element.

29. An electronic apparatus comprising:
a switching circuit including a first circuit and a second circuit; and
a controller for controlling the switching circuit,
wherein the first circuit is configured to process a signal of a first sensor element,
wherein the second circuit is configured to process a signal of a second sensor element,
wherein the controller is configured to switch between the first circuit and the second circuit of the switching circuit, and
wherein the switching circuit includes:
an operational amplifier having an inverted input terminal, a non-inverted input terminal, and an output terminal;
a resistor connectable to the inverted input terminal and the output terminal; and
a second resistor connectable to the inverted input terminal and the output terminal.
